(19) United States
(12) Patent Application Publication
(10) Pub. No.: US 2015/0086464 A1
(43) Pub. Date: Mar. 26, 2015

(54) METHOD OF PRODUCING MONOCRYSTALLINE SILICON

(71) Applicant: GTAT Corporation, Merrimack, NH (US)

(72) Inventors: Scott J. Turchetti, Peterborough, NH (US); Ning Duanmu, Nashua, NH (US)

(73) Assignee: GTAT CORPORATION, Merrimack, NH (US)

(21) Appl. No.: 14/375,016

(22) PCT Filed: Dec. 5, 2012
(86) PCT No.: PCT/US12/67917

§ 371 Date: Jul. 28, 2014

Related U.S. Application Data
(60) Provisional application No. 61/591,474, filed on Jan. 27, 2012.

(51) Int. Cl. C30B 11/00; C30B 11/14; C30B 29/06; C30B 11/02

(52) U.S. Cl. CPC C30B 11/003; C30B 11/02; C30B 11/14; C30B 11/006; C30B 29/06
USPC 423/348; 117/83

(57) ABSTRACT

A method of producing a crystalline product comprising a high percentage by volume monocrystalline material in a crystal growth apparatus is disclosed. The method comprises the steps of providing a crucible comprising feedstock and at least one monocrystalline seed, melting the feedstock without substantially melting the monocrystalline seed under controlled conditions, and forming the crystalline product by solidification of the melt also under controlled conditions. The resulting crystalline product comprises greater than 50% by volume monocrystalline material.

### CROSS-REFERENCE TO RELATED APPLICATIONS

The present application is the U.S. national stage of PCT/US2012/067917 filed Dec. 5, 2012, which claims the benefit of U.S. patent application Ser. No. 61/591,474, filed Jan. 27, 2012.

### BACKGROUND OF THE INVENTION

1. Field of the Invention.

The present invention relates to an apparatus and method for producing a crystalline material, as well as to a crystalline material having a high percentage by volume of monocrystalline silicon.

2. Description of the Related Art.

Crystal growth apparatuses or furnaces, such as directional solidification systems (DSS) and heat exchanger method (HEM) furnaces, involve the melting and controlled resolidification of a feedstock material, such as silicon, in a crucible to produce a crystalline material, often referred to as an ingot. Production of a solidified ingot from molten feedstock occurs in several identifiable steps over many hours. For example, to produce a silicon ingot by the DSS method, solid silicon feedstock is provided in a crucible, often contained in a graphite crucible box, and placed into the hot zone of a DSS furnace. The feedstock is then heated to form a liquid feedstock melt, and the furnace temperature, which is well above the silicon melting temperature of 1412° C., is maintained for several hours to ensure complete melting. Once fully melted, heat is removed from the melted feedstock, often by applying a temperature gradient in the hot zone, in order to directionally solidify the melt and form a silicon ingot. By controlling how the melt solidifies, an ingot having greater purity than the starting feedstock material charged to the crucible can be achieved. This material can then be used in a variety of high end applications, such as in the semiconductor and photovoltaic industries.

In a typical solidification of silicon feedstock, the resulting solidified silicon ingot is generally multicrystalline, having random small crystal grain sizes and orientations. It has also been shown that a silicon ingot comprising monocrystalline (i.e. single crystal) silicon can also be formed. For example, to produce a monocrystalline silicon ingot using either a DSS or HEM process, one or more solid seeds of monocrystalline silicon can be placed along the bottom of a crucible, along with the silicon feedstock, and then heated to melt. If at least a part of the seeds is maintained after the feedstock has fully melted, directional crystallization of the melt occurs corresponding to the crystal orientation of the monocrystalline seed.

Typically, as the directional solidification of a monocrystalline silicon ingot occurs, regions of multicrystalline silicon also form, most often along the outside edges of the ingot (sometimes referred to as edge growth), particularly when a single seed is placed in the center of the crucible bottom. For example, crystals may nucleate from surfaces other than the seed, producing considerable amounts of multicrystalline silicon. It has been shown that larger regions of monocrystalline material can be formed when the entire bottom of the crucible is covered with a single large seed or a plurality of smaller seeds placed against each other (also called tiling). However, due to conditions used to grow the crystalline ingot, it has been observed that edge growth typically still occurs as crystals will nucleate from the cooling crucible sides. This reduces the size of the monocrystalline portion of the resulting product, lowering the yield. As a result, monocrystalline silicon yields of less than 50% are typical.

Therefore, in order to obtain a crystalline product having a large region of monocrystalline material, an improved process and crystal growth apparatus is needed to carefully control melt and growth conditions, thereby maximizing the amount of monocrystalline material formed.

### SUMMARY OF THE INVENTION

The present invention further relates to a method of producing a monocrystalline material. The method comprises the steps of providing a crystal growth apparatus comprising specified components, melting the silicon feedstock without substantially melting the at least one monocrystalline silicon seed, and forming the crystalline material. In particular, the crystal growth apparatus comprises a hot zone surrounded by an insulation cage, a crucible placed within the hot zone having at least one monocrystalline silicon seed arranged on the bottom and silicon feedstock arranged on top of the monocrystalline silicon seeds, an upper thermocouple positioned above the crucible, and a resistance heating system comprising a top heater positioned above the crucible and at least one side heater positioned around sides of the crucible, wherein the top heater and the side heaters are configured to be independently supplied with power. The step of melting the silicon feedstock without substantially melting the at least one monocrystalline silicon seed comprises heating the hot zone to a target temperature above the melting point of silicon, as measured by the upper thermocouple, by supplying power independently to the top heater and the side heaters in a first top heater/side heater power ratio; opening the insulation cage beneath the crucible upon reaching the target temperature; and changing the power independently supplied to the top heater and the side heaters to a second top heater/side heater power ratio that is greater than the first top heater/side heater power ratio. The step of forming the crystalline material comprises removing heat from the hot zone and changing the power independently supplied to the top heater and the side heaters to a final top heater/side heater power ratio that is less than the first top heater/side heater power ratio. The crystalline material comprises greater than 50% by volume monocrystalline silicon and preferably comprises greater than 80% by volume monocrystalline silicon. The present invention also relates to this monocrystalline silicon material as well as the apparatus for preparing it.

It is to be understood that both the foregoing general description and the following detailed description are exemplary and explanatory only and are intended to provide further explanation of the present invention, as claimed.

### BRIEF DESCRIPTION OF THE DRAWINGS

FIG. 1 is a cross-sectional view a crystal growth apparatus used in an embodiment of the method of the present invention.

### DETAILED DESCRIPTION OF THE INVENTION

The present invention relates to methods of growing a crystalline material having a large monocrystalline silicon region.

The method of the present invention is a method of producing a crystalline material, including, for example, a silicon ingot or sapphire. The method comprises the steps of providing a crystal growth apparatus having various components, particularly having a top and a side heater, and controlling the heat input for melting and heat removal for growth in specific ways to produce a crystalline product having high monocrystalline yields.

The crystal growth apparatus used in the method of the present invention is a furnace, in particular a high-temperature furnace, capable of heating and melting a solid feedstock, such as silicon, at temperatures generally greater than about 1000° C. and subsequently promoting resolidification of the resulting melted feedstock material to form a crystalline material. For example, the crystal growth apparatus can be a directional solidification system (DSS) crystal growth furnace or a heat exchanger method (HEM) crystal growth furnace, but is preferably a DSS furnace.

The crystal growth apparatus comprises an outer furnace chamber or shell and an interior hot zone within the furnace shell. The furnace shell can be any known in the art used for high temperature crystallization furnaces, including a stainless steel shell comprising an outer wall and an inner wall defining a cooling channel for circulation of a cooling fluid, such as water. The hot zone of the crystal growth apparatus is an interior region within the furnace in which heat can be provided and controlled to melt and resolidify a feedstock material, described in more detail below. The hot zone is surrounded by and defined by insulation, which can be any material known in the art that possesses low thermal conductivity and is capable of withstanding the temperatures and conditions in a high temperature crystal growth furnace. For example, the hot zone can be surrounded by insulation of graphite. The shape and dimension of the hot zone can be formed by a plurality of insulation panels, some of which can be either stationary or mobile. For example, the hot zone may be formed of top, side, and bottom insulation panels, with the top and side insulation panels configured to move vertically relative to a crucible placed within the hot zone.

The hot zone comprises a crucible capable of containing at least feedstock material, described in more detail below. The crucible can be made of various heat resistant materials known in the art including, for example, quartz (silica), graphite, silicon carbide, silicon nitride, composites of silicon carbon or silicon nitride with silica, pyrolytic boron nitride, alumina, or zirconia and, optionally, may be coated, such as with silicon nitride, to prevent cracking of the ingot after solidification. The crucible can also have a variety of different shapes having at least one side and a bottom, including, for example, cylindrical, cubic or cuboid (having a square cross-section), or tapered. Preferably, when the feedstock is silicon, the crucible is made of silica and has a cube or cuboid shape.

The crucible within the hot zone contains a charge used to form a crystalline product, such as sapphire or a silicon ingot, comprising a region of monocrystalline material, which is a region of the crystalline product having one consistent crystal orientation throughout. Preferably, the crystalline material is silicon and comprises a monocrystalline silicon region that is greater than 50% by volume of the silicon ingot and can be anywhere throughout the product, such as in the center. More preferably, the crystalline material is greater than 60% by volume monocrystalline silicon, including greater than 70% and greater than 80% monocrystalline silicon.

The charge in the crucible comprises feedstock material, such as alumina or polycrystalline or multicrystalline silicon, which can be in any form known in the art, including powder, pellets, or larger chunks or pieces. The charge further comprises at least one monocrystalline seed, which comprises the same material as the feedstock except having a single crystal orientation throughout. For example, the crucible can comprise silicon feedstock placed upon at least one monocrystalline silicon seed. Preferably, the charge comprises a plurality of monocrystalline seeds, which can be arranged along the bottom of the crucible. Any type of seed crystal known in the art can be used. For example, the monocrystalline seeds may be circular or polygonal, such as square or rectangular, in cross-sectional shape. Also, each of the seeds preferably has a flat lower surface to provide good contact with the interior surface of the bottom of the crucible, and, more preferably, further has a flat upper surface as well. The number of monocrystalline seeds can vary depending, for example, on the inner dimensions of the crucible used and on the size of the seeds. For example, from 2 to 36 square monocrystalline seeds can be arranged around the interior crucible bottom. As a particular example, 25 square seeds can be arranged in a 5 by 5 pattern on the bottom of the crucible. The monocrystalline seeds can range in size from about 10 cm to about 85 cm along any edge. Preferably the seeds are arranged in a pattern to substantially fully cover the interior surface of the crucible bottom, being placed as close to the inside edges and corners of the crucible as is practically possible. Such a placement is sometimes referred to as tiling. Thus, preferably, the plurality of monocrystalline seeds are arranged or tiled along the inside bottom surface of the crucible so that each seed is in contact with a neighboring or adjacent seed, forming a close-packed arrangement. The thickness of the seeds can also vary, depending on availability and cost. For example, the seeds may have a thickness of about 0.5 cm to about 5 cm, including from about 1 cm to about 4 cm and from about 2 cm to about 3 cm. Preferably, all of the seeds are substantially similar in size, shape, and thickness.

The crucible can optionally be contained within a crucible box, which provides support and rigidity for the sides and bottom of the crucible and is particularly preferred for crucibles made of materials that are either prone to damage, cracking, or softening, especially when heated. For example, a crucible box is preferred for a silica crucible but may be unnecessary for a crucible made of silicon carbide, silicon nitride, or composites of silicon carbide or silicon nitride with silica. The crucible box can be made of various heat resistant materials, such as graphite, and typically comprises at least one side plate and a bottom plate, optionally further comprising a lid. For example, for a cube or cuboid-shaped crucible, the crucible box is preferably also in the shape of a cube or cuboid, having four walls and a bottom plate, with an optional lid. The crucible and optional crucible box can be provided on top of a crucible support block within the hot zone, which further can be supported on a plurality of pedestals in order to place the crucible into a central position in the crystal growth apparatus. The crucible support block can be made of any heat resistant material, such as graphite, and is preferably a similar material to the crucible box, if used.

The hot zone further comprises at least one thermocouple by which the temperature therein is monitored and/or controlled. The thermocouple can be any known in the art capable of measuring high temperatures associated with heating, melting and resolidifying of feedstock material. For example, the thermocouple can comprise a thermocouple sensor encased in heat-protecting tubes housed in a protective sheath, for example, made of graphite. In addition, the thermocouple can be arranged anywhere within the hot zone including from which the temperature can be properly determined. For example, the hot zone may comprise an upper thermocouple positioned above the crucible, at a position near the top heating element. Additional thermocouples can also be used and can be positioned at other locations within the hot zone, such as below or beside the crucible along its outer surfaces.

The hot zone further comprises at least one heating system to provide heat to melt the feedstock placed within the crucible. The heating system is a resistance heating system comprising multiple heating elements, each being resistive heaters in which current flows through the element, causing it to heat up. The resistive heating elements can be designed with any material known in the art including, for example, graphite, platinum, molybdenum disilicide, silicon carbide, or metal alloys such as nickel chromium or iron-chromium-aluminum alloys. In particular, the hot zone comprises a first or top heating element, positioned above the crucible, preferably horizontally in the upper region of the hot zone, providing heat from above, and at least one second or side heating element positioned along the sides of the crucible, preferably vertically along the sides of the hot zone below the first heating element. The side heating elements preferably surround the outer periphery of crucible and optional crucible box. The heating elements can be any shape or size known in the art. For example, the side heating elements can have a size and overall shape similar to the vertical cross sectional shape of the crucible, and the top heating element can have a size and overall shape similar to the horizontal cross sectional shape of the crucible. The top heating element can also be circular in shape. The temperature in the hot zone may be controlled by independently regulating the power provided to the various resistive heating elements and can use either a single controller or multiple controllers. As such, the first or top heating element and the second or side heating element can be controlled independently.

The crystal growth apparatus used in the method of the present invention further comprises at least one means for removing heat from the hot zone. When the apparatus is a DSS furnace, the means for removing the heat can comprise movable sections of the insulation that surrounds the hot zone and the crucible provided therein. For example, the top and side insulation panels of the hot zone can be configured to move vertically while the bottom insulation panel is configured to remain stationary. Alternatively, as another example, the top and side insulation panels may be configured to remain stationary while the bottom insulation panel is configured to move vertically. Other combinations are also possible. In this way, heat may be removed without moving the crucible. When the apparatus is a HEM furnace, the means for removing heat from the hot zone can be a heat exchanger, such as a helium-cooled heat exchanger, provided to be in thermal communication with the bottom of the crucible placed within the hot zone.

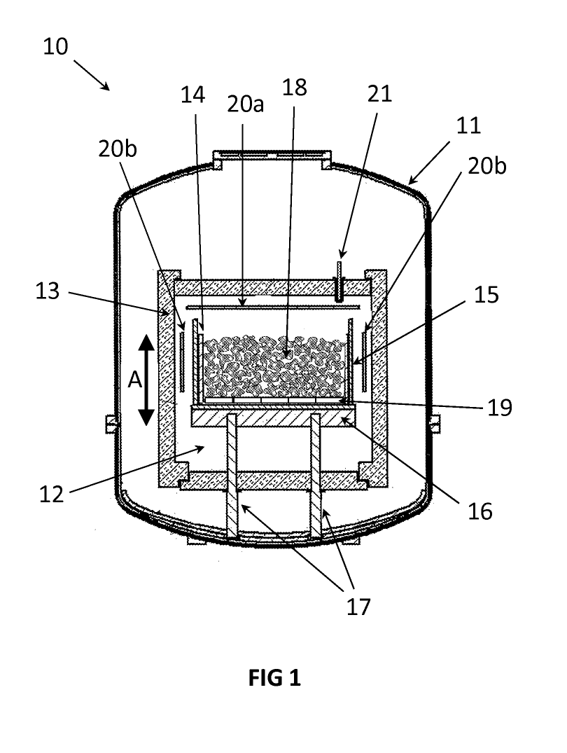

FIG. 1 is a cross-sectional view of an embodiment of the crystal growth apparatus that can be used in the method of the present invention. It should be apparent to those skilled in the art that this is merely illustrative in nature and not limiting, being presented by way of example only. Numerous modifications and other embodiments are within the scope of one of ordinary skill in the art and are contemplated as falling within the scope of the present invention. In addition, those skilled in the art should appreciate that the specific configurations are exemplary and that actual configurations will depend on the specific system. Those skilled in the art will also be able to recognize and identify equivalents to the specific elements shown, using no more than routine experimentation.

The crystal growth apparatus 10 shown in FIG. 1 comprises a furnace shell 11 and hot zone 12 within furnace shell 11 surrounded and defined by insulation cage 13. Crucible 14 within crucible box 15 is provided in hot zone 12 atop crucible support block 16 supported on pedestals 17 and contains silicon feedstock 18 on top of monocrystalline silicon seeds 19, which, as shown, are arranged along the bottom of crucible 14 and substantially fully cover the entire bottom, with edges of one seed abutting an edge of at least one neighboring seed. Silicon feedstock 18 can also be provided along the sides and edges of monocrystalline silicon seeds 19 if space is available. Hot zone 12 further includes a heating system comprising top heater 20a positioned above crucible 14 and side heater 20b positioned around the sides of crucible 14. The heaters are independently controlled by a controller (not shown) which provides power to each heater, thereby heating hot zone 12. Insulation cage 13 is movable vertically, as shown by arrow A, and this is the primary means for removing heat from the hot zone of crystal growth apparatus 10 from beneath crucible 14, exposing hot zone 12 and the components contained therein to outer chamber 11, which is cooled using a cooling medium such as water. The temperature within the hot zone is monitored and/or controlled by upper thermocouple 21.

With the crucible, containing feedstock material and at least one monocrystalline seed, being provided in the hot zone of the crystal growth apparatus, the method of the present invention further comprises the step of melting the feedstock without substantially melting the monocrystalline seed. For this feedstock melting step, the hot zone is heated to a target temperature that is greater than the melting temperature of the feedstock by supplying power to the top heater and the side heaters in a controlled manner. In particular, if the feedstock is silicon and the monocrystalline seeds are monocrystalline silicon seeds, power is supplied to the heaters in an amount sufficient to raise the temperature in the hot zone, as measured, for example, by the upper thermocouple described above, to be greater than 1420° C., preferably greater than 1450° C., and more preferably greater than 1500° C., such as from about 1500° C. to about 1550° C. To reach this target temperature, power is supplied independently to the top heater and the side heater in a specified ratio, herein referred to as the “top heater/side heater power ratio”. In particular, in order to melt the feedstock in a direction from the top of the crucible downward to the monocrystalline seeds, and, further, to achieve melt in as short a time as possible, relatively more power is provided to the top heater compared to the side heater. Thus, power is supplied to the top heater and side heaters in a first top heater/side heater power ratio that is greater than 50/50, such as from about 50/50 to about 60/40. Slight adjustments to this first top heater/side heater power ratio can also be made to further optimize total melt time, taking care to ensure that the crucible does not become damaged by cracking due to excessive rapid heating.

Once the target temperature has been reached, the temperature in the hot zone of the crystal growth apparatus is then maintained under specific conditions in order to melt the feedstock without substantially melting the monocrystalline seed. In particular, for the method of the present invention, once the target temperature has been reached, the insulation cage surrounding the hot zone is opened, thereby creating a gap beneath the crucible. The amount that the insulation cage is opened depends on a variety of factors, including, for example, the amount of feedstock to be melted, the size of the insulation cage, and the desired time to achieve feedstock melt. For example, the cage can be opened from about 6 to about 10 cm. This can be done gradually or in incremental steps, but is preferably done in as short a time as possible. Since moving the insulation creates a gap beneath the crucible, allowing heat in the hot zone to escape to the cooler walls of the crystal growth apparatus, it is also within the scope of the present invention to increase the temperature in the hot zone to compensate for this heat loss.

Subsequent to, or simultaneously with, the opening of the cage, the power ratio between the top heater and the side heater is also changed. In particular, more power is provided to the top heater compared to the side heater in order to reach a second top heater/side heater power ratio that is greater than the first top heater/side heater power ratio. The amount depends on, for example, the desired time to achieve melting of the feedstock. For example, the power can be changed to a second top heater/side heater power ratio which is from about 50/50 to about 80/20, including from about 60/40 to about 70/30. The ratio can be changed either in discreet increments (i.e., stepwise) or continuously to the desired second power ratio. By shifting more power to the top heater while, or as, the insulation cage is opened, sufficient heat can be provided to the hot zone in order to melt the feedstock, while, at the same time, the monocrystalline seeds, which are in thermal contact with the relatively cooler bottom of the crucible, can be protected against significant melting.

If the feedstock is not fully melted after achieving the second top heater/side heater power ratio, heating can be continued, with the insulation cage opened and the power shifted, until substantially all of the feedstock has melted but without substantially melting of the monocrystalline seeds. The amount of seed remaining can be determined using any method known in the art, although measurement of the extent of seed melting is not required for the present method. If desired, for example, a quartz dip rod may be inserted into the melt, such as from above the crucible, at various time intervals to determine the extent of melt, based on the height of the rod. Preferably 90% or more of the seed surface area is maintained, and, more preferably, 95% or more of the seed surface area remains.

After melting the feedstock of the charge without substantially melting the monocrystalline seeds, the method of the present invention further comprises the step of forming or growing the crystalline material. To begin growth, heat is removed from the hot zone of the crystal growth apparatus, and any method known in the art can be used to remove heat to from the crystalline material, depending on the type of crystal growth apparatus. For example, in a DSS furnace, directional solidification of the melt can be achieved through controlled heat extraction from the crucible by gradually increasing radiant heat losses to the water-cooled chamber through the bottom of the hot zone. In a HEM furnace, a heat exchanger can be used to extract heat from below. In the method of the present invention, which preferably utilizes a DSS furnace, removing heat from the hot zone in order to form the crystalline material can comprise opening the insulation cage further, reducing the temperature in the hot zone, which thereby reduces the total power to the top and side heaters, or a combination thereof. For example, to form a silicon ingot, the temperature in the hot zone may be lowered and, subsequently or simultaneously, the insulation cage can be further opened, such as from about 1 to about 8 cm, in order to allow heat to escape the hot zone from below the crucible, thereby solidifying the silicon in an upward direction. The temperature can be lowered to a value that is similar to, but preferably not significantly below, the melting point of the feedstock.

In order to further promote formation of a crystalline material having a high volume of monocrystalline material, the power independently supplied to the top heater and the side heater is also changed. This can be done subsequent to the start of removal of the heat from the hot zone or simultaneously with it. In particular, the relative amount of total power provided to the side heaters is increased while the relative amount of total power provided to the top heater is reduced, thereby reaching a final top heater/side heater power ratio that is less than the second top heater/side heater power ratio and, preferably, is also less than the first top heater/side heater power ratio. Thus, the final power ratio is less than 50/50 and is preferably from about 45/65 to about 0/100 (i.e., all of the power provided to the side heaters). More preferably, the final power ratio is from about 40/60 to about 10/90. By shifting power to the side heaters, heat is provided to the crucible sides, thereby promoting solidification from the monocrystalline seeds and reducing the likelihood of crystal growth initiating from the side walls. This has been found to increase the amount of monocrystalline material resulting in the final crystalline product. The power supplied to the heaters may be changed continuously or incrementally in order to reach the final top heater/side heater power ratio. For example, power can first be shifted to the side heaters to reach an intermediate top heater/side heater power ratio, such as from about 20/80 to about 10/90 for an initial phase of solidification and, subsequently changed to the final top heater/side heater power ratio, such as to about 40/60 to about 30/70, to increase the growth rate and shorten the overall process cycle time. Other changes can also be used. The resulting crystalline material can optionally be annealed and can then be removed from the crucible.

It has been found that the method of the present invention has significant advantages over known methods for preparing crystalline products, and, further, that the resulting product has improved properties, including significantly improved amount of monocrystalline material. In particular, independently adjusting the relative amount of power to the top heater and the side heaters in specific ways during critical phases of the crystal growth process has been found to provide outstanding process control that has not been previously possible. For example, during the melt stage, more heat is provided to the upper portion of the charge rather than the sides which, combined with opening of the insulation cage, enables controlled melting of the charge in the crucible. By controlling the melt stage in this way, the feedstock can be melted without substantial melting of the valuable seeds used to promote monocrystalline growth. This could permit the use of use of thinner seeds, which are substantial cost of this process. In addition, it has also been found that the growth or solidification of the desired crystalline material can also be controlled using the same crystal growth apparatus components by providing a greater amount of heat along the sides of the crucible and less from above. This minimizes initiation of crystallization from sites other than the monocrystalline seeds. Thus, using the method of the present invention, a crystalline product, such as a silicon ingot, can be prepared reliably and predictably having a percentage by volume of monocrystalline material, such as monocrystalline silicon, that is significantly greater than can be prepared using currently available crystal growth methods or apparatuses.

Thus, the present invention further relates to a crystalline product comprising a monocrystalline region that is 50% or more of the total product volume. For example, the crystalline product can be a crystalline silicon material, such as a silicon ingot, comprising greater than about 50% by volume monocrystalline silicon, including greater than about 60%, greater than about 70%, greater than about 80%, and greater than about 85% monocrystalline silicon. The monocrystalline region is preferably an interior region of the crystalline material, and therefore the product further comprises an exterior multicrystalline region.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A method of producing a crystalline material comprising the steps of
i) providing a crystal growth apparatus comprising
a hot zone surrounded by an insulation cage,
a crucible placed within the hot zone, wherein the crucible comprises at least one monocrystalline silicon seed arranged on a bottom of the crucible and silicon feedstock arranged on top of the monocrystalline silicon seeds,
an upper thermocouple positioned above the crucible, and
a heating system comprising a top heater positioned above the crucible and at least one side heater positioned around sides of the crucible, wherein the top heater and the side heaters are configured to be independently supplied with power;
ii) melting the silicon feedstock without substantially melting the at least one monocrystalline silicon seed, comprising
a) heating the hot zone to a target temperature above the melting point of silicon, as measured by the upper thermocouple, by supplying power independently to the top heater and the side heaters in a first top heater/side heater power ratio;
b) opening the insulation cage beneath the crucible upon reaching the target temperature; and
c) changing the power independently supplied to the top heater and the side heaters to a second top heater/side heater power ratio, wherein the second top heater/side heater power ratio is greater than the first top heater/side heater power ratio, thereby melting the silicon feedstock without substantially melting the at least one monocrystalline silicon seed; and
iii) forming the crystalline material comprising
a) removing heat from the hot zone and
b) changing the power independently supplied to the top heater and the side heaters to a final top heater/side heater power ratio, wherein the final top heater/side heater power ratio is less than the first top heater/side heater power ratio, thereby forming the crystalline material, wherein the crystalline material comprises greater than 50% by volume monocrystalline silicon.

2. The method of claim 1, wherein the crystal growth apparatus is a directional solidification furnace.

3. The method of claim 1, wherein the target temperature is between about 1500° C. and 1550° C.

4. The method of claim 1, wherein, in the step of melting the silicon feedstock, power is supplied to the top heater in an amount greater than to the side heater.

5. The method of claim 4, wherein the first top heater/side heater power ratio is from about 50/50 to about 60/40.

6. The method of claim 1, wherein, in the step of melting the silicon feedstock, the power supplied to the top heater and the side heaters is changed after the insulation cage is opened.

7. The method of claim 1, wherein, in the step of melting the silicon feedstock, the power supplied to the top heater and the side heaters is changed as the insulation cage is opened.

8. The method of claim 1, wherein the second top heater/side heater power ratio is from about 50/50 to about 80/20.

9. The method of claim 8, wherein the second top heater/side heater power ratio is from about 60/40 to about 70/30.

10. The method of claim 1, wherein, in the step of melting the silicon feedstock, the power supplied to the top heater and the side heaters is changed in incremental steps to the second top heater/side heater power ratio.

11. The method of claim 1, wherein, in the step of melting the silicon feedstock, the monocrystalline seed has a seed surface area that is 95% maintained after the silicon feedstock is melted.

12. The method of claim 1, wherein, in the step of forming the crystalline material, heat is removed from the hot zone by further opening the insulation cage.

13. The method of claim 12, wherein the insulation cage is opened continuously as the power supplied to the top heater and the side heaters is changed.

14. The method of claim 1, wherein, in the step of forming the crystalline material, heat is removed from the hot zone by lowering the temperature in the hot zone.

15. The method of claim 1, wherein, in the step of forming the crystalline material, the power supplied to the top heater and the side heaters is changed after heat is removed from the hot zone.

16. The method of claim 1, wherein, in the step of forming the crystalline material, the power supplied to the top heater and the side heaters is changed as heat is removed from the hot zone.

17. The method of claim 1, wherein, in the step of forming the crystalline material, power is supplied to the top heater in an amount less than to the side heaters.

18. The method of claim 17, wherein the final top heater/side heater power ratio is from about 45/65 to about 10/90.

19. The method of claim 17, wherein the final top heater/side heater power ratio is from about 40/60 to about 20/80.

20. The method of claim 1, wherein, in the step of forming the crystalline material, the power supplied to the top heater and the side heaters is changed in incremental steps to the final top heater/side heater power ratio.

21. The method of claim 1, wherein the crystalline material comprises greater than 60% monocrystalline silicon.

22. The method of claim 1, wherein the crystalline material comprises greater than 70% monocrystalline silicon.

23. The method of claim 1, wherein the crystalline material comprises greater than 80% monocrystalline silicon.

24. A crystalline silicon material comprising greater than 80% monocrystalline silicon.
